(19) United States
(12) Patent Application Publication
(10) Pub. No.: US 2021/0312858 A1
(43) Pub. Date: Oct. 7, 2021

(54) LIGHT-EMITTING COMPONENT PACKAGE MODULE FOR DISPLAY AND BACKLIGHT AND DISPLAY

(71) Applicant: Chin-Chih CHENG, Hsinchu County (TW)

(72) Inventors: Chin-Chih CHENG, Hsinchu County (TW); Ching-Chung CHENG, Hsinchu County (TW)

(21) Appl. No.: 17/220,780

(22) Filed: Apr. 1, 2021

(30) Foreign Application Priority Data
Apr. 7, 2020 (TW) 109111588

(51) Int. Cl. G09G 3/32; H01L 33/62; H01L 27/15

(52) U.S. Cl. CPC G09G 3/32; G09G 2310/08; H01L 27/156; H01L 33/62

(57) ABSTRACT

A light-emitting component package module for a display and a backlight includes a drive module and an LED light module. The LED light module includes multiples of two LED light assemblies, and the drive module controls the brightness of the multiples of two LED light assemblies according to a drive signal provided by a control module.

### BACKGROUND

### Technical Field

The present disclosure relates to a light-emitting component package module for a display and a backlight, and more particularly to a light-emitting component package module in which a drive module and LED light assemblies are packaged together for a display and a backlight.

### Description of Related Art

The statements in this section merely provide background information related to the present disclosure and do not necessarily constitute prior art.

With the advancement of optoelectronic technology, the range of optoelectronic applications has become wider, and the light-emitting diodes (LEDs) are the most common application in the field of displays. Please refer to FIG. 1A, which shows a circuit diagram of a related-art panel of a display using LEDs. A panel 100A of the display 100 is composed of matrix-type LEDs D11-Dmn+1. Each row of the matrix includes switches SW1-SWm and each row has current commands Ci1-Cin+1. The control module 2 sequentially turns on switches SW1-SWm by a frequency-sweeping manner to sequentially light up each row of the LEDs D11-Dmn+1 according to the current commands Ci1-Cin+1.

Please refer to FIG. 1B, which shows a waveform diagram of controlling the related-art display. The current commands Ci1-Cin+1 use a PWM (pulse-width modulation) technology to control the brightness of the LEDs D11-Dmn+1. The wider the pulse width, the brighter the brightness of the LEDs D11-Dmn+1; the narrower the pulse width, the darker the brightness of the LEDs D11-Dmn+1. In addition, there is a dead time Td between each switch SW1-SWm being turned on to avoid two rows of LEDs D11-Dmn+1 lighting up at the same time. However, this control manner must be controlled by switches SW1-SWm, which will cause the turned-on width of the current commands Ci1-Cin+1 to keep getting smaller resulting in insufficient output pulse width, which will cause poor display effect of the LEDs D11-Dmn+1. If the turned-on frequency of the switches SW1-SWm is increased, the turned-on time will continue to decrease so that the switches SW1-SWm cannot be fully opened during the pulse width time or the output of the LEDs D11-Dmn+1 is incomplete.

### SUMMARY

In order to solve the above-mentioned problems, the present disclosure provides a light-emitting component package module for a display and a backlight. The light-emitting component package module includes a drive module and an LED light module. The drive module receives a drive signal of a control module. The LED light module includes multiples of two LED light assemblies coupled to the drive module. The drive module controls the brightness of the multiples of two LED light assemblies according to the drive signal.

In one embodiment, the multiples of two LED light assemblies are respectively arranged in equal number at both sides along an axis, and the drive module is coupled to the multiples of two LED light assemblies without blocking light source paths of the multiples of two LED light assemblies.

In one embodiment, the multiple is a power of two; the multiples of two LED light assemblies are respectively arranged in equal number in a first quadrant, a second quadrant, a third quadrant, and a fourth quadrant of a coordinate; the drive module is arranged in an origin of the coordinate.

In one embodiment, the drive signal includes an enabled signal and a current command assembly. The drive module includes a timing control unit and a current storage module. The timing control unit receives the enabled signal. The current storage module includes multiples of two current storage units corresponding to the multiples of two LED light assemblies. Each current storage unit receives the current command assembly. The timing control unit provides multiples of two control signals to correspondingly drive the multiples of two current storage units according to the enabled signal. The driven current storage units control the brightness of the corresponding LED light assemblies according to the current command assembly.

In one embodiment, each LED light assembly includes a red LED light, a green LED light, and a blue LED light, and the current command assembly includes a red light current command, a green light current command, and a blue light current command. Each current storage unit controls the brightness of the red LED light according to the red light current command, controls the brightness of the green LED light according to the green light current command, and controls the brightness of the blue LED light according to the blue light current command; or each LED light assembly comprises an LED light and the current command assembly comprises a current command, and each current storage unit controls the brightness of the LED light according to the current command.

In one embodiment, each current storage unit includes at least one current adjustment circuit, and each of the at least one current adjustment circuit includes a path switch unit, a current adjustment unit, a first switch unit, and a first energy-storing unit. The path switch unit is coupled to one of the current commands of the current command assembly, and receives one of the multiples of two control signals. The current adjustment unit is coupled to the path switch unit and one of the LED lights of one of the LED light assemblies. The first switch unit is coupled to the current adjustment unit, and receives one of the control signals of the multiples of two control signals. The first energy-storing unit is coupled to the first switch unit and the current adjustment unit. When one of the control signals is transited from a first level to a second level, the current adjustment unit receives one of the current commands of the current command assembly by turning on the path switch unit, and the first energy-storing unit stores a first drive voltage of driving the current adjustment unit by turning on the first switch unit. The current adjustment unit driven by the first drive voltage generates a drive current according to one of the current commands to control the brightness of one of the LED lights.

In one embodiment, when one of the control signals is transited from the second level to the first level, the path switch unit is turned off so that the current adjustment unit fails to receive one of the current commands, and the first switch unit is turned off so that the first energy-storing unit provides the remaining first drive voltage to drive the current adjustment unit. The current adjustment unit maintains the brightness of one of the LED lights according to the first drive voltage.

In one embodiment, each of the at least one current adjustment circuit includes an energy-releasing switch. The energy-releasing switch is coupled to the first energy-storing unit, and receives an energy-releasing signal. When the energy-releasing switch is turned on by the energy-releasing signal, the first drive voltage releases energy through the energy-releasing switch and fails to drive the current adjustment unit.

In one embodiment, each of the at least one current adjustment circuit includes a second switch unit, a cascade unit, and a second energy-storing unit. The second switch unit is coupled to the current adjustment unit, and receives one of the control signals. The cascade unit is coupled to the second switch unit and the current adjustment unit. The second energy-storing unit is coupled to the second switch unit and the cascade unit. When one of the control signals is transited from the first level to the second level, the second energy-storing unit stores a second drive voltage of driving the cascade unit by turning on the second switch unit. The cascade unit driven by the second drive voltage controls an end voltage of the current adjustment unit, and the end voltage fixes a ratio between one of the current commands and the drive current.

In one embodiment, the current adjustment unit includes a first transistor and a second transistor. The first transistor has an input end, an output end, and a control end. The input end is coupled to the path switch unit, the output end is coupled to a ground end, and the control end is coupled to the first switch unit and the first energy-storing unit. The second transistor has an input end, an output end, and a control end. The input end is coupled to one of the LED lights, the output end is coupled to the ground end, and the control end is coupled to the control end of the first transistor. When the first switch unit is turned on, one of the current commands charges the first energy-storing unit so that the first energy-storing unit stores the first drive voltage, and the first drive voltage turns on the first transistor and the second transistor. When the path switch unit is turned on, one of the current commands flows from the input end of the first transistor to the output end of the first transistor, and the drive current corresponding to one of the current commands is generated from the input end of the second transistor to the output end of the second transistor by mirroring. The drive current flows through one of the LED lights to control the brightness of one of the LED lights.

In one embodiment, when the path switch unit and the switch unit are turned off, one of the current commands does not charge the energy-storing unit so that the energy-storing unit provides the remaining first drive voltage to turn on the second transistor to maintain the brightness of one of the LED lights.

In one embodiment, the cascade unit includes a third transistor and a fourth transistor. The third transistor has an input end, an output end, and a control end. The input end is coupled to the path switch unit, the output end is coupled to the input end of the first transistor, and the control end is coupled to the second switch unit and the second energy-storing unit. The fourth transistor has an input end, an output end, and a control end. The input end is coupled to one of the LED lights, the output end is coupled to the input end of the second transistor, and the control end is coupled to the output end of the second transistor. When the second switch unit is turned on, the second energy-storing unit is charged so that the second energy-storing unit stores the second drive voltage, and the second drive voltage turns on the third transistor and the fourth transistor. The third transistor is turned on so that the input end of the first transistor has the end voltage, and the fourth transistor is turned on so that a node voltage of the input end of the second transistor is adjusted to be equal to the end voltage and a current value of the drive current is equal to a current value of one of the current commands.

In order to solve the above-mentioned problems, the present disclosure provides a display. The display includes a light-emitting matrix and a control module. The light-emitting matrix includes a plurality of rows or a plurality of columns. Each row or each column includes a plurality of light-emitting component package modules. The control module is coupled to the light-emitting matrix. The control module provides a plurality of enabled signals to sequentially drive the plurality of rows or the plurality of columns.

In one embodiment, the control module provides a plurality of enabled signals in a frequency-sweeping loop to sequentially drive the plurality of rows or the plurality of columns.

In one embodiment, an un-driven time period is defined as that an elapsed time of one of plurality of rows or one of the plurality of columns be driven twice in the frequency-sweeping loop. During the un-driven time period, the light-emitting component package modules of one of the rows or of one of the columns adjust the brightness of the LED light assemblies according to the corresponding current command assembly.

The main purpose and effect of the present disclosure is that the light-emitting component package module uses a special packaging structure composed the drive module and the LED light assembly so that the display can easily use this packaging structure to form the panel, and the light-emitting component package module is driven by the drive module without using the conventional switches.

It is to be understood that both the foregoing general description and the following detailed description are exemplary, and are intended to provide further explanation of the present disclosure as claimed. Other advantages and features of the present disclosure will be apparent from the following description, drawings and claims.

### BRIEF DESCRIPTION OF DRAWINGS

The present disclosure can be more fully understood by reading the following detailed description of the embodiment, with reference made to the accompanying drawing as follows:

FIG. 1A is a circuit diagram of a related-art panel of a display using LEDs.

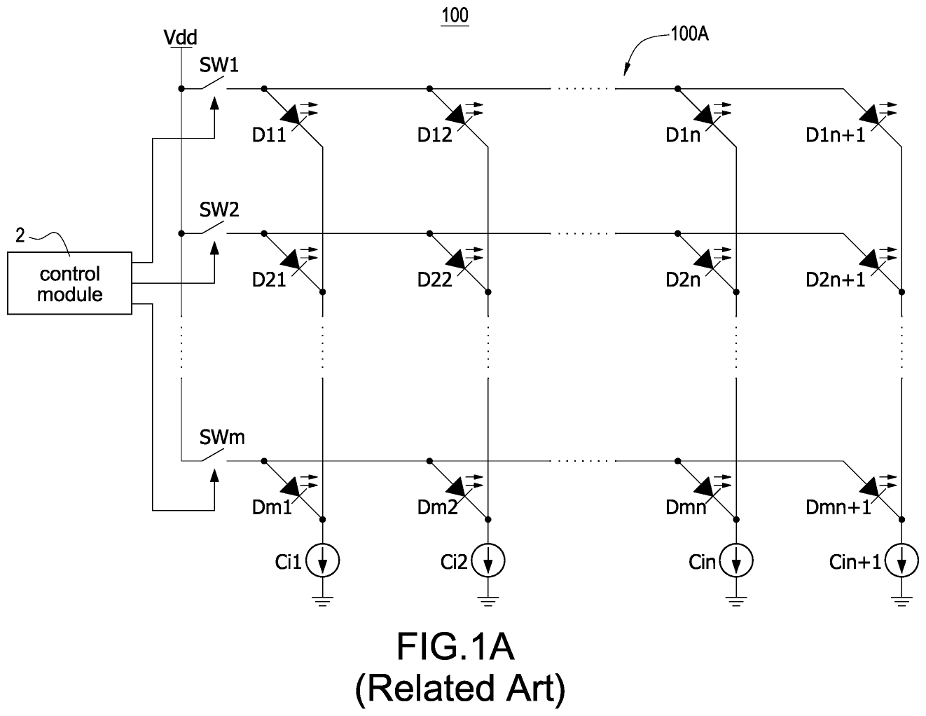

FIG. 1B is a waveform diagram of controlling the related-art display.

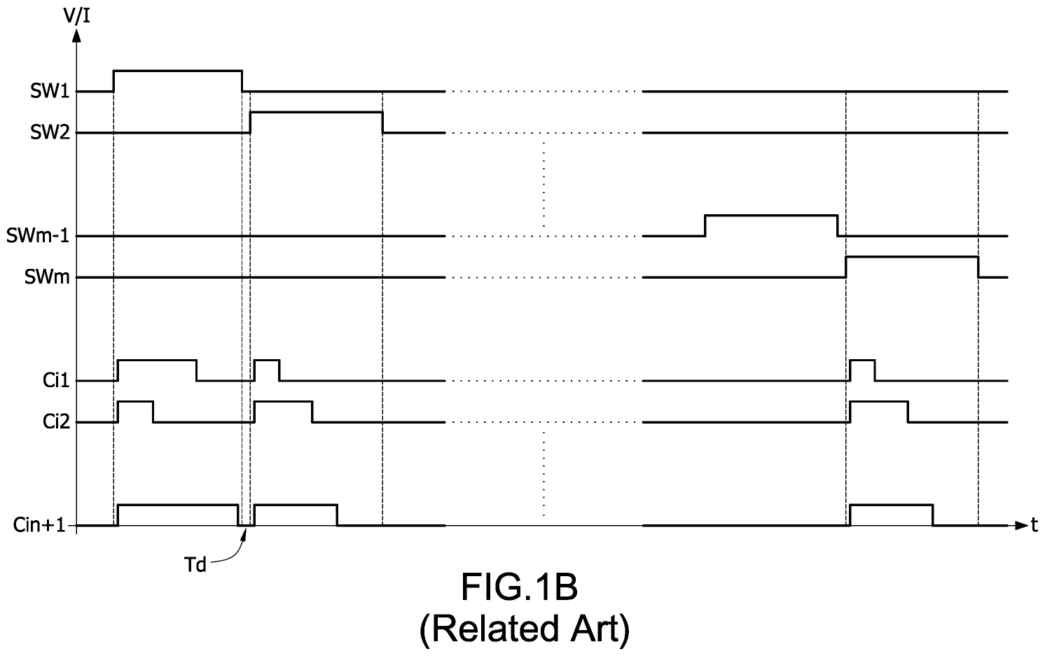

FIG. 2 is a block diagram of a light-emitting component package module for a display and a backlight according to the present disclosure.

FIG. 3A is a schematic structure diagram of LED light assemblies according to a first embodiment of the present disclosure.

FIG. 3B is a schematic structure diagram of LED light assemblies according to a second embodiment of the present disclosure.

FIG. 3C is a schematic structure diagram of LED light assemblies according to a third embodiment of the present disclosure.

FIG. 4 is a block circuit diagram of a drive module according to the present disclosure.

FIG. 5 is a block circuit diagram of a timing control unit according to the present disclosure.

FIG. 6A is a block circuit diagram of a current storage module according to a first embodiment of the present disclosure.

FIG. 6B is a circuit diagram of a current adjustment circuit according to a first detailed circuit of the first embodiment of the present disclosure.

FIG. 6C is a circuit diagram of a current adjustment circuit according to a second detailed circuit of the first embodiment of the present disclosure.

FIG. 7A is a block circuit diagram of a current storage module according to a second embodiment of the present disclosure.

FIG. 7B is a block circuit diagram of the current storage module according to a detailed of the second embodiment of the present disclosure.

FIG. 7C is a block circuit diagram of the current storage module according to a detailed of the third embodiment of the present disclosure.

FIG. 8 is a block diagram of a display composed of light-emitting component package modules according to the present disclosure.

FIG. 9 is a waveform diagram of controlling the light-emitting component package module according to the present disclosure.

### DETAILED DESCRIPTION

Reference will now be made to the drawing figures to describe the present disclosure in detail. It will be understood that the drawing figures and exemplified embodiments of present disclosure are not limited to the details thereof.

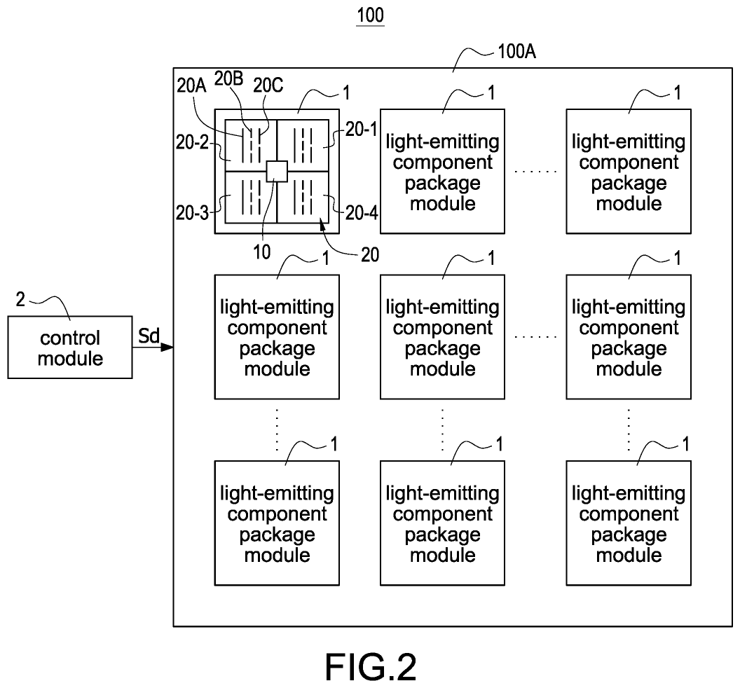

Please refer to FIG. 2, which shows a block diagram of a light-emitting component package module for a display and a backlight according to the present disclosure. The light-emitting component package module 1 is applied to a panel 100A of a display 100. The panel 100A includes a plurality of light-emitting component package modules 1, and the light-emitting component package modules 1 are driven to light by a control module 2. The light-emitting component package module 1 includes a drive module 10 and an LED light module 20. The LED light module 20 includes multiples of two LED light assemblies 20-1,20-2 (for ease of illustration, only two LED light assemblies 20-1,20-2 are shown in FIG. 2). Each LED light assembly 20-1,20-2 includes a red LED light 20A, a green LED light 20B, and a blue LED light 20C, and each LED light assembly 20-1,20-2 forms a pixel. Alternatively, each LED light assembly 20-1,20-2 includes a white light LED light or a single-primary-color LED light (such as, but not limited to a single blue LED light). The drive module 10 is coupled to the control module 2 and the two LED light assemblies 20-1,20-2, and the drive module 10 respectively controls the brightness of the two LED light assemblies 20-1,20-2 according to a drive signal Sd provided by the control module 2.

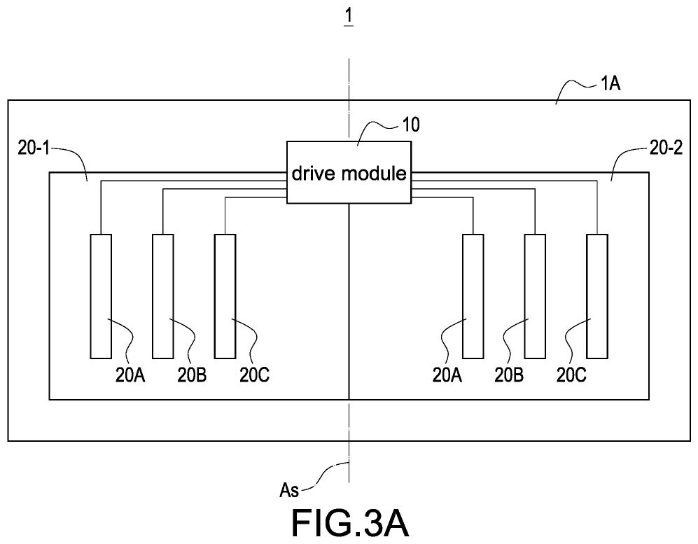

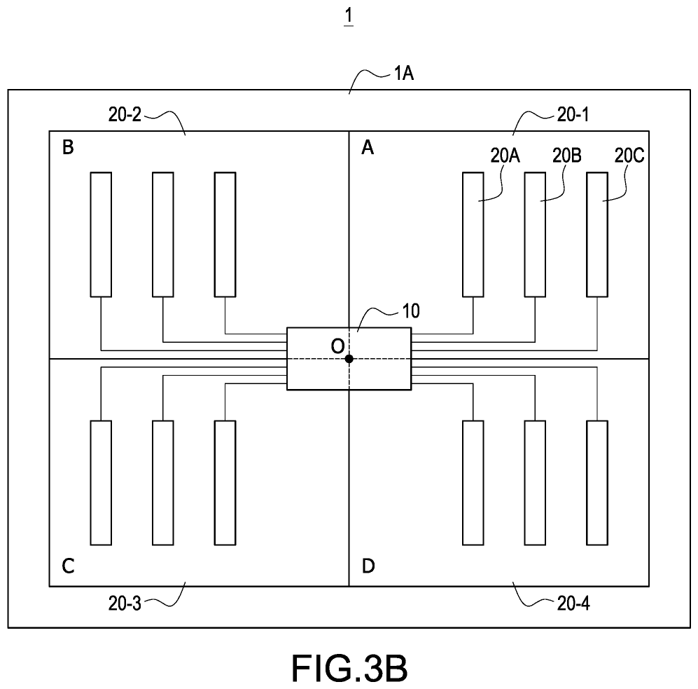

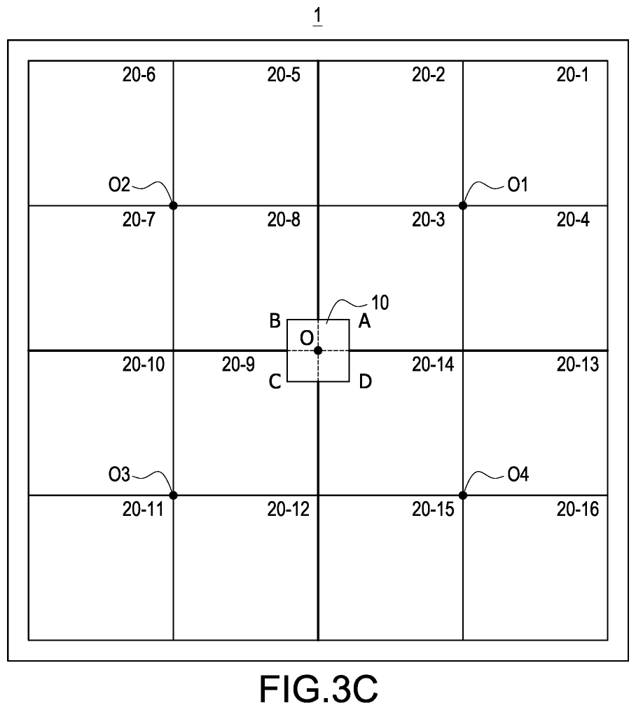

Please refer to FIG. 3A, which shows a schematic structure diagram of LED light assemblies according to a first embodiment of the present disclosure, FIG. 3B, which shows a schematic structure diagram of LED light assemblies according to a second embodiment of the present disclosure, and FIG. 3C, which shows a schematic structure diagram of LED light assemblies according to a third embodiment of the present disclosure, and also refer to FIG. 2. As shown in FIG. 3A, it is assumed that each LED light assembly has a three-primary-color LED light (20A-20C) and there are two LED light assemblies 20-1,20-2, i.e., the multiple is 1. The two LED light assemblies 20-1,20-2 are respectively arranged (disposed) in equal number at both sides along an axis As. The drive module 10 may be arranged (disposed) at any position inside an accommodation space of the light-emitting component package module 1, and is coupled to the two three-primary-color LED light assemblies 20-1,20-2. The position of the drive module 10 is designed so as not to block light source paths of red LED light 20A, the green LED light 20B, and the blue LED light 20C of the two three-primary-color LED light assemblies 20-1,20-2. Take FIG. 3A as an example, the drive module 10 is arranged on the axis As. The packaging technology (such as but not limited to, a wire bonding or a flip chip) is used to connect the wires and the components on the base 1A, and finally package them together to form the light-emitting component package module 1.

As shown in FIG. 3B, it is assumed that each LED light assembly has a three-primary-color LED light (20A-20C) and there are four LED light assemblies 20-1 to 20-4, i.e., the multiple is two. The four LED light assemblies 20-1 to 20-4 are respectively arranged (disposed) in the first quadrant A, the second quadrant B, the third quadrant C, and the fourth quadrant D, and the control module 2 is arranged (disposed) at the origin O of the coordinate. The drive module 10 (including wires coupling to the four LED light assemblies 20-1 to 20-4) is arranged (disposed) at the origin O of the coordinate. Afterward, the four LED light assemblies 20-1 to 20-4 and the drive module 10 are packaged together to form one light-emitting component package module 1 by using a packaging technology.

As shown in FIG. 3C, it is assumed that each LED light assembly has a three-primary-color LED light (20A-20C) and there are 16 LED light assemblies 20-1 to 20-16, i.e., the multiple is eight. Every four LED light assemblies of the 16 LED light assemblies 20-1 to 20-16 are respectively arranged (disposed) in the first quadrant A, the second quadrant B, the third quadrant C, and the fourth quadrant D, and the control module 2 is arranged (disposed) at the origin O of the coordinate. The drive module 10 (including wires coupling to the four LED light assemblies 20-1 to 20-16, but the LED lights not shown) is arranged (disposed) at the origin O of the coordinate. Afterward, the 16 LED light assemblies 20-1 to 20-16 and the drive module 10 are packaged together to form one light-emitting component package module 1 by using a packaging technology. When the multiple is another positive integer, is may follow the analogy in FIG. 3A to FIG. 3C, and the detail description is omitted here for conciseness. In one embodiment, if the multiple is greater than or equal to eight, the assembly or part of the drive module 10 may be also individually or separately set at origins O1-O4, which may be adjusted according to actual needs.

Since the structure of the light-emitting component package module 1 is relatively small, the dies of the red LED lights 20A, the green LED lights 20B, and the blue LED lights 20C of the LED light assemblies 20-1,20-2 (shown in FIG. 3A) are usually mounted (adhered) on a base 1A. Afterward, the packaging technology (such as but not limited to, a wire bonding or a flip chip) is used to connect the wires and the components on the base 1A, and finally package them together. The base 1A may be four pieces, or put together into a single piece. If the multiple is a power of four (i.e., four, sixteen, and so on), the optimal position of arranging the drive module 10 is the origin O of the coordinate in order to prevent the components and circuits of the drive module 10 from affecting the light source path of the three-primary-color LED light assemblies 20-1 to 20-4. Therefore, the main purpose of the present disclosure is that the light-emitting component package module 1 uses the packaging structure composed of the drive module 10 and the LED light assemblies 20-1,20-2 so that the display 100 can easily use this packaging structure to form the panel 100A, and the light-emitting component package module 1 is driven by the drive module 10 without using the conventional switches SW1-SWm.

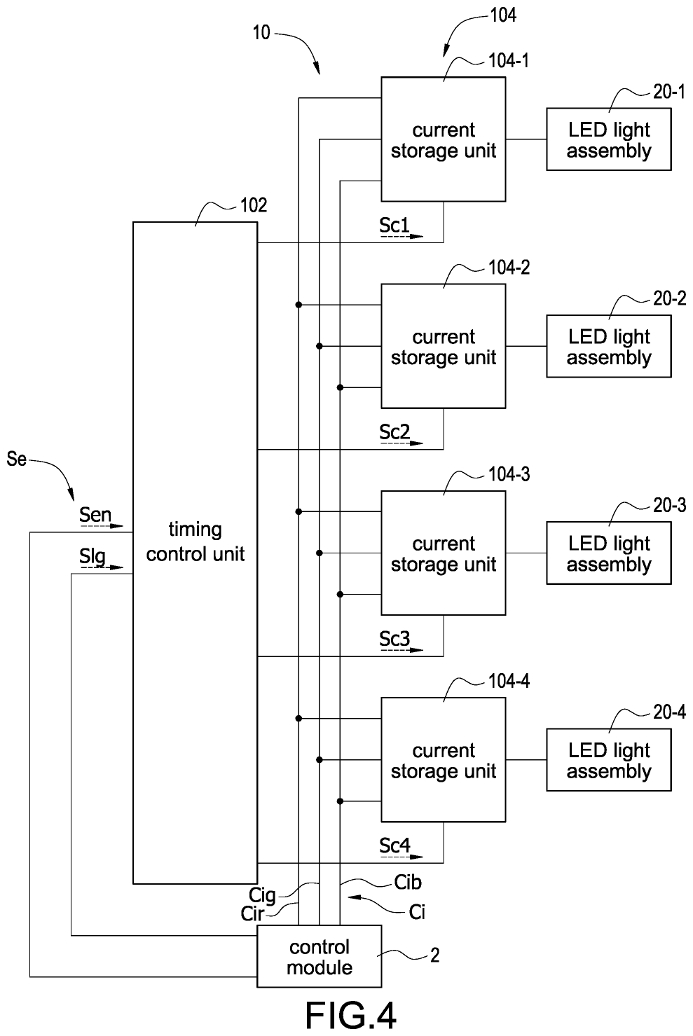

Please refer to FIG. 4, which shows a block circuit diagram of a drive module according to the present disclosure, and also refer to FIG. 2 to FIG. 3C. Take the structure of FIG. 3 as an example, the drive module 10 includes a timing control unit 102 and a current storage module 104. The current storage module 104 includes multiples of two current storage units 104-1 to 104-4. The number of the current storage units 104-1 to 104-4 is equal to the number of the LED light assemblies 20-1 to 20-4. The drive signal Sd includes an enabled signal Se and a current command Ci. The enabled signal Se includes an activation signal Sen and a logic signal assembly Slg. The timing control unit 102 is coupled to the control module 2, and receives the activation signal Sen and the logic signal assembly Slg. The current storage units 104-1 to 104-4 are coupled to the timing control unit 102 and the control module 2, and are respectively coupled to the LED light assemblies 20-1 to 20-4. The timing control unit 102 generates multiples of two control signals Sc1-Sc4 according to the activation signal Sen and the logic signal assembly Slg, and provides the control signals Sc1-Sc4 to the corresponding current storage units 104-1 to 104-4. The number of the control signals Sc1-Sc4 is equal to the number of the current storage units 104-1 to 104-4. The timing control unit 102 provides the control signals Sc1-Sc4 to drive the current storage units 104-1 to 104-4, and the driven current storage units 104-1 to 104-4 control the brightness of the corresponding LED light assemblies 20-1 to 20-4 according to a current command assembly Ci provided by the control module 2.

When the LED light assembly 20-1 has the three-primary-color LED lights, the current command assembly Ci includes the red light current command Cir, the green light current command Cig, and the blue light current command Cib. Each current storage unit 104-1 to 104-4 controls the brightness of the red LED light 20A according to the red light current command Cir, controls the brightness of the green LED light 20B according to the green light current command Cig, and controls the brightness of the blue LED light 20C according to the blue light current command Cib. When the LED light assembly 20-1 has only a single LED light, the current command assembly Ci includes only a single current command provided by a single line to control the single LED light. For example, but not limited to, the LED light assembly 20-1 has a white LED light, and the current command assembly Ci includes the white light current command (not shown). Each current storage unit 104-1 to 104-4 controls the brightness of the white LED light according to the white light current command.

Furthermore, the timing control unit 102 may simultaneously provide the control signals Sc1-Sc4 according to the changes of the logic signal assembly Slg and the activation signal Sen so as to simultaneously drive the current storage units 104-1 to 104-4. Alternatively, the timing control unit 102 may provide the control signals Sc1-Sc4 in a time-sharing manner according to the changes of the logic signal assembly Slg and the activation signal Sen so as to sequentially drive the current storage units 104-1 to 104-4. Since the current storage units 104-1 to 104-4 may be simultaneously driven by the four control signals Sc1-Sc4, the current command assembly Ci may not provide enough current to the current storage units 104-1 to 104-4. At this condition, the brightness of the LED light assemblies 20-1 to 20-4 may not reach the brightness required by the control module 2. Therefore, by sequentially driving the current storage units 104-1 to 104-4 in the time-sharing manner by the control signals Sc1-Sc4, the current of the current command assembly Ci can be accurately provided to the current storage units 104-1 to 104-4 in each time period. Accordingly, the brightness of the LED light assemblies 20-1 to 20-4 can be accurately controlled. Moreover, since the number of frames captured by the naked eye per second is much smaller than the time-sharing frequency of the control signals Sc1-Sc4, the time-sharing control manner of providing control signals Sc1-Sc4 will not affect the visual effect obtained by the naked eye. Therefore, the timing control unit 102 provides the four control signals Sc1-Sc4 in the time-sharing manner to sequentially drive the current storage units 104-1 to 104-4, which is a preferred embodiment.

For example, the timing control unit 102 provides the first control signal Sc1, the second control signal Sc2, the third control signal Sc3, and the fourth control signal Sc4 in the time-sharing manner to sequentially drive the first current storage unit 104-1, the second current storage unit 104-2, the third current storage unit 104-3, and the fourth current storage unit 104-4 according to the changes of “00”, “01”, “10”, and “11” of the logic signal assembly Slg and the activation signal Sen. The driven current storage units 104-1 to 104-4 controls the brightness of the red LED light 20A according to the red light current command Cir, controls the brightness of the green LED light 20B according to the green light current command Cig, and controls the brightness of the blue LED light 20C according to the blue light current command Cib.

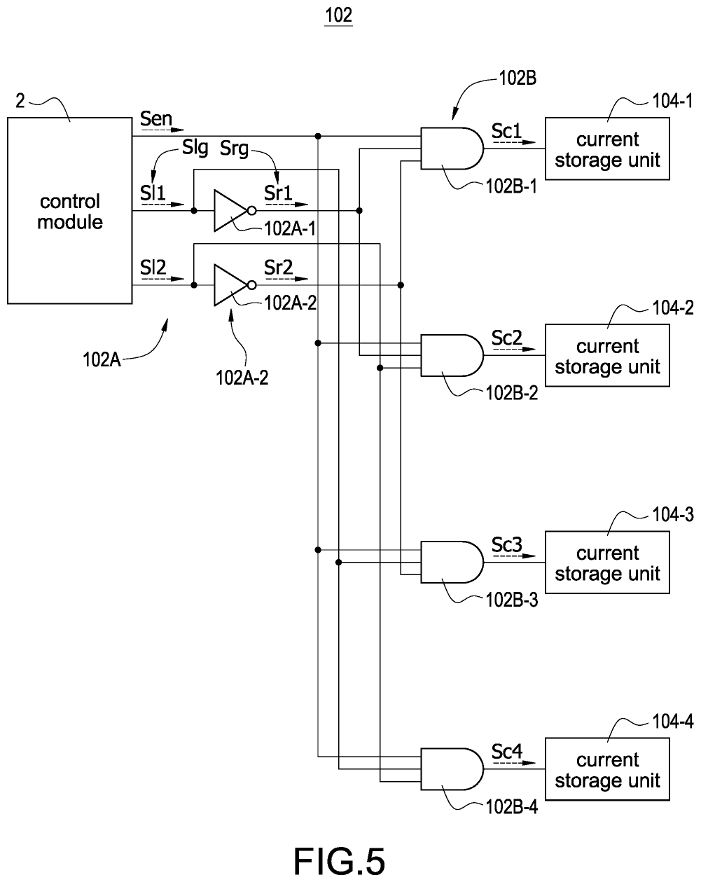

Please refer to FIG. 5, which shows a block circuit diagram of a timing control unit according to the present disclosure, and also refer to FIG. 2 to FIG. 4. Take the timing control unit 102 providing four control signals Sc1-Sc4 in a time-sharing manner as an example. The timing control unit 102 includes a NOT gate unit 102A and an AND gate unit 102B. The NOT gate unit 102A is coupled to the control module 2 and the AND gate unit 102B. The AND gate unit 102B is coupled to the current storage units 104-1 to 104-4. The NOT gate unit 102A receives the logic signal assembly Slg, and inverts the logic signal assembly Slg to provide an inverted logic signal assembly Srg to the AND gate unit 102B. The AND gate unit 102B receives the activation signal Sen, the logic signal assembly Slg, and the inverted logic signal assembly Srg, and provides the control signals Sc1-Sc4 in a time-sharing manner according to the activation signal Sen, the logic signal assembly Slg, and the inverted logic signal assembly Srg to sequentially drive the current storage units 140-1 to 104-4. In one embodiment, when the timing control unit 102 simultaneously provides the control signals Sc1-Sc4 to drive the current storage units 104-1 to 104-4, the timing control unit 102 may be a signal transmission line. That is, the enabled signal Se of the control module 2 is respectively provided to the current storage units 104-1 to 104-4 through the transmission line of the timing control unit 102, and the enabled signal Se, the logic signal assembly Slg, and the activation signal Sen are the same signal.

The AND gate unit 102B includes multiples of two AND gates 102B-1 to 102B-4, and output ends of the AND gates 102B-1 to 102B-4 are respectively coupled to the current storage units 104-1 to 104-4. The number of the AND gates 102B-1 to 102B-4 is equal to the number of the current storage units 104-1 to 104-4. The NOT gate unit 102A includes multiple of one NOT gates 102A-1 to 102A-2, the logic signal assembly Slg includes multiple of one logic signals Sl1-Sl2, and the inverted logic signal assembly Srg includes multiple of one inverted logic signals Sr1-Sr2. The NOT gates 102A-1 to 102A-2 correspondingly invert/convert the logic signals Sl1-Sl2 into the inverted logic signals Sr1-Sr2. The logic signals Sl1-Sl2 are respectively (not repeatedly) provided to two AND gates 102B-1 to 102B-4, and the inverted logic signals Sr1-Sr2 are respectively (not repeatedly) provided to two AND gates 102B-1 to 102B-4. Therefore, each AND gate 102B-1 to 102B-4 receives the activation signal Sen, one of the logic signals Sl1-Sl2, and one of the inverted logic signals Sr1-Sr2. The logic signals Sl1-Sl2 are expressed in two states of “0” and “1”, and therefore four combinations are produced based on the logic signals Sl1-Sl2 and the inverted logic signals Sr1-Sr2. By the changes of the logic signals Sl1-Sl2, only one AND gate 102B-1 to 102B-4 receives the logic-1 input signal in every time period. Therefore, with the four combinations and the enabled signal Sen, the control signals Sc1-Sc4 generated by the AND gates 102B-1 to 102B-4 have the effect of sequentially driving the current storage units 104-1 to 104-4 according to timing changes. That is, four LED light assemblies 20-1 to 20-4 can be simultaneously driven by pairs of the logic signals Sl1-Sl2 and the inverted logic signals Sr1-Sr2, and the light-emitting time interval may be determined without interfering according to the activation signal Sen. In one embodiment, the circuit structure of the timing control unit 102 is not limited to be implemented in FIG. 5. As long as the timing change can be provided and the timing control unit 102 that sequentially provides the control signals Sc1-Sc4, it should be included in the scope of this embodiment.

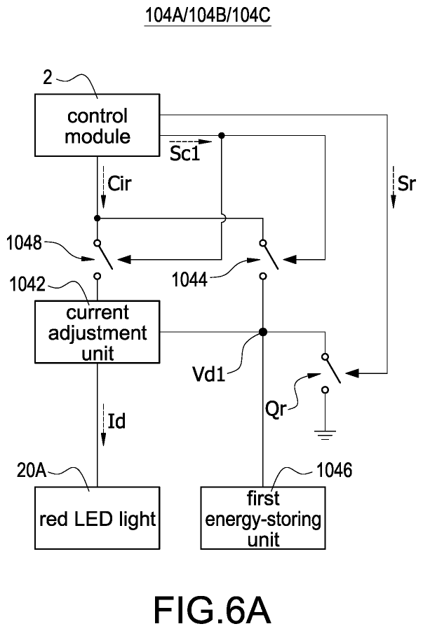

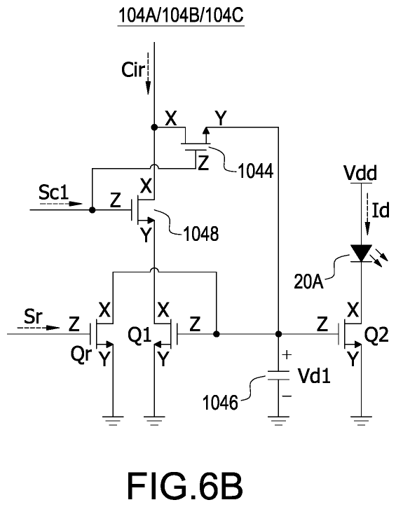

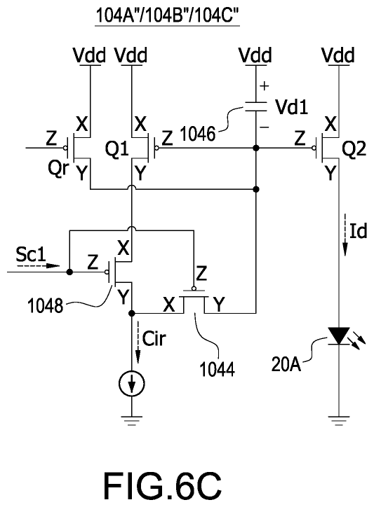

Please refer to FIG. 6A, which shows a block circuit diagram of a current storage module according to a first embodiment of the present disclosure, and also refer to FIG. 2 to FIG. 5. Each current storage unit 104-1 to 104-4 includes three current adjustment circuits 104A-104C (only one current adjustment circuit is exemplified for demonstration). Each current adjustment circuit 104A-104C includes a current adjustment unit 1042, a first switch unit 1044, a first energy-storing unit 1046, and a path switch unit 1048. The current adjustment unit 1042 is coupled to the control module 2 and one (take a red LED light 20A as an example) of the LED lights 20A-20C of one of the LED light assemblies 20-1 to 20-4, and receives one (take a red light current command Cir as an example) of current commands Cir,Cig,Cib of the current command assembly Ci. The first switch unit 1044 is coupled to the current adjustment unit 1042, and receives one (take a control signal Sc1 as an example) of multiples of four control signals Sc1-Sc4. The first energy-storing unit 1046 is coupled to the first switch unit 1044 and the current adjustment unit 1042. When the first switch unit 1044 is turned on, the first energy-storing unit 1046 stores a first drive voltage Vd1. The path switch unit 1048 is coupled between the control module 2 and the current adjustment unit 1042, and receives one (take a control signal Sc1 as an example) of multiples of two control signals Sc1-Sc4. In particular, the function of the path switch unit 1048 is: when the current adjustment circuits 104A-104C of the path switch unit 1048 do not need to write the current commands Cir,Cig,Cib, the path switch unit 1048 should be turned off so as to avoid affecting other current adjustment circuits 104A-104C, which are writing current commands Cir,Cig,Cib, due to the continuously consumed current commands to write wrong (incorrect) current commands, and solve the problem of insufficient brightness while simultaneously driving the current storage units 104-1 to 104-4.

When the control signal Sc1 is transited from a first level (for example, a lower signal level) to a second level (for example, a higher signal level), the path switch unit 1048 and the first switch unit 1044 are turned on. One of the current commands Cir,Cig,Cib of the current command assembly Ci is provided to (flows to) the current adjustment unit 1042 through the path switch unit 1048. The first energy-storing unit 1046 stores the first drive voltage Vd1 of driving the current adjustment unit 1042 by turning on the first switch unit 1044. In particular, the first drive voltage Vd1 may be acquired by flowing one of the current commands Cir,Cib,Cib to the first energy-storing unit 1046 through the first switch unit 1044, or acquired by charging the first energy-storing unit 1046 through the first switch unit 1044 to a node voltage, which is converted or divided by the current adjustment unit 1042, or acquired by charging the first energy-storing unit 1046 through the first switch unit 1044 to an external voltage. The current adjustment unit 1042 driven by the first drive voltage Vd1 generates a drive current Id according to one of the current commands Cir,Cig,Cib. The drive current Id flows through one of the LED lights 20A-20C (corresponding to one of the current commands Cir,Cig,Cib) so that one of the LED lights 20A-20C lights up. When the drive current Id is larger, the brightness of one of the LED lights 20A-20C is higher; when the drive current Id is smaller, the brightness of one of the LED lights 20A-20C is lower.

When the control signal Sc1 is transited from the second level (for example, a higher signal level) to the first level (for example, a lower signal level), the path switch unit 1048 and the first switch unit 1044 are turned off. One of the current commands Cir,Cig,Cib of the current command assembly Ci is not provided to (does not flow to) the current adjustment unit 1042 through the path switch unit 1048. The first energy-storing unit 1046 fails to acquire energy through the first switch unit 1044 so that the first energy-storing unit 1046 provides the remaining first drive voltage Vd1 to drive the current adjustment unit 1042. When the path switch unit 1048 and the first switch unit 1044 are turned off, the stored first drive voltage Vd1 can still drive the current adjustment unit 1042 since the first energy-storing unit 1046 still has the stored first drive voltage Vd1 so that the current adjustment unit 1042 still operates. Although the path switch unit 1048 and the first switch unit 1044 are turned off, the current adjustment unit 1042 still maintains the current value before the path switch unit 1048 and the first switch unit 1044 are turned off so as to maintain the brightness of one of the LED lights 20A-20C.

When the first switch unit 1044 is turned off, the first drive voltage Vd1 will gradually be consumed. When the first drive voltage Vd1 is consumed to fail to drive the current adjustment unit 1042, the current adjustment unit 1042 can no longer control the brightness of one of the LED lights 20A-20C. Although the light-emitting component package module 1 is mainly applied to the display 100 using a frequency-sweeping (time-division multiplexing) technology, the frequency of the control signal Sc1 needs to be limited by the rate of consumption of the first drive voltage Vd1. In particular, the rate of consumption of the first drive voltage Vd1 is determined based on the picture recognition by the human eye's. That is, after the first switch unit 1044 is turned off and before the first drive voltage Vd1 is consumed until the current adjustment unit 1042 cannot be driven, the first level of the control signal Sc1 is preferably converted to the second level thereof so as to avoid the current adjustment unit 1042 from being unable to control one of the LED lights 20A-20C.

Each current adjustment circuit 104A-104C further an energy-releasing switch Qr. The energy-releasing switch Qr is coupled between the first energy-storing unit 1046 and a ground end. A control end of the energy-releasing switch Qr is coupled to the control module 2, and receives an energy-releasing signal Sr provided by the control module 2. When the energy-releasing signal Sr controls turning on the energy-releasing switch Qr, the first drive voltage Vd1 is released to the ground end through the energy-releasing switch Qr so that the first energy-storing unit 1046 has no energy and fails to drive the current adjustment unit 1042. Specifically, when one of the LED lights 20A-20C does not need to emit light (or does not need to mix color), the control module 2 provides the energy-releasing signal Sr to turn on the energy-releasing switch Qr, which is coupled to the current adjustment circuit 104A-104C of one of the LED lights 20A-20C, so that the current adjustment unit 1042 of the current adjustment circuit 104A-104C fails to be driven. Therefore, one of the LED lights 20A-20C does not emit light.

Please refer to FIG. 6B, which shows a circuit diagram of a current adjustment circuit according to a first detailed circuit of the first embodiment of the present disclosure, and also refer to FIG. 2 to FIG. 6A. As shown in FIG. 6A, the current adjustment unit 1042 of each current adjustment circuit 104A-104C (only one current adjustment circuit 104A-104C is exemplified for demonstration) includes a first transistor Q1 and a second transistor Q2. Both the first transistor Q1 and the second transistor Q2 has an input end X, an output end Y, and a control end Z. An input end X of the path switch unit 1048 is coupled to the control module 2 and an input end X of the first switch unit 1044, and a control end Z of the path switch unit 1048 is coupled to a control end Z of the first switch unit 1044. The input end X of the first transistor Q1 is coupled to an output end Y of the path switch unit 1048, the output end Y of the first transistor Q1 is coupled to the ground end, and the control end Z of the first transistor Q1 is coupled to an output end Y of the first switch unit 1044 and a first end of the first energy-storing unit 1046. The input end X of the second transistor Q2 is coupled to a first end of one of the LED lights 20A-20C, and a second end of one of the LED lights 20A-20C is coupled to a working voltage Vdd. The output end Y of the second transistor Q2 is coupled to the ground end, and the control end Z of the second transistor Q2 is coupled to the control end Z of the first transistor Q1. The energy-releasing switch Qr is coupled to the first end of the first energy-storing unit 1046, the control end Z of the first transistor Q1, and the control end Z of the second transistor Q2.

When the control signal Sc1 is transited from the first level (for example, a lower signal level) to a second level (for example, a higher signal level), the path switch unit 1048 and the first switch unit 1044 are turned on. One of the current commands Cir,Cig,Cib of the current command assembly Ci is provided to (flows to) the first transistor Q1 through the path switch unit 1048. One of the current commands Cir,Cig,Cib charges the first energy-storing unit 1046 through the first switch unit 1044 so that the first energy-storing unit 1046 stores the first drive voltage Vd1. When the voltage value of the first drive voltage Vd1 rises enough to turn on the first transistor Q1 and the second transistor Q2, the first drive voltage Vd1 turns on the first transistor Q1 and the second transistor Q2 to drive the current adjustment unit 1042. At this condition, the first transistor Q1 is turned on so that a current path is generated from the input end X of the first transistor Q1 to the output end Y thereof, and therefore one of the current commands Cir,Cig,Cib flows from the input end X of the first transistor Q1 to the output end Y thereof. In one embodiment, since the current adjustment unit 1042 is a current mirror circuit, a drive current Id of one of the current commands Cir,Cig,Cib is correspondingly generated according to the working voltage Vdd to the input end X and the output end Y of the second transistor Q2. The drive current Id flows through one of the LED lights 20A-20C to light up one of the LED lights 20A-20C, and the amplitude of the drive current Id control the changes in brightness of one of LED lights 20A-20C.

When the control signal Sc1 is transited from the second level (for example, a higher signal level) to the first level (for example, a lower signal level), the path switch unit 1048 and the first switch unit 1044 are turned off. One of the current commands Cir,Cig,Cib of the current command assembly Ci is not provided to (does not flow to) the first transistor Q1 through the path switch unit 1048, and one of the current commands Cir,Cig,Cib no longer charges the first energy-storing unit 1046. When the energy-releasing switch Qr is not turned on, the first drive voltage Vd1 stored in the first energy-storing unit 1046 will be not released. At this condition, the first energy-storing unit 1046 can still provide the stored first drive voltage Vd1 to turn on the second transistor Q2. Therefore, the current adjustment unit 1042 can still generate the drive current Id to flow through one of the LED lights 20A-20C through the working voltage Vdd and the first drive voltage Vd1 to maintain the brightness of one of the LED lights 20A-20C.

When the energy-releasing switch Qr is turned on, the remaining first drive voltage Vd1 of the first energy-storing unit 1046 will be released from the path of the input end X and output end Y of the energy-releasing switch Qr to the ground end so that the current adjustment unit 1042 is not driven and one of the LED lights 20A-20C does not emit light. Therefore, one of the current commands Cir,Cig,Cib charges the first energy-storing unit 1046 to generate the first drive voltage Vd1, and then the first switch unit 1044 is immediately turned off (similar to a writing manner), and therefore one of the LED lights 20A-20C can still be control to emit light without providing the control signal Sc1 with the first level. Also, a clear (reset) manner by turning on the energy-releasing switch Qr to release the first drive voltage Vd1 to the ground may be used to stop driving the current adjustment unit 1042 when one of the LED lights 20A-20C does not need to emit light. In one embodiment, the current adjustment unit 1042 is not limited to be implemented by using the current-mirror circuit. As long as the current adjustment unit 1042 can correspondingly generate the drive current Id according to one of the current commands Cir,Cig,Cib, it should be included in the scope of this embodiment.

Please refer to FIG. 6C, which shows a circuit diagram of a current adjustment circuit according to a second detailed circuit of the first embodiment of the present disclosure, and also refer to FIG. 2 to FIG. 6B. The difference between the current adjustment circuit 104A″-104C″ in this embodiment and the current adjustment circuit 104A-104C shown in FIG. 6B is that the circuit structure of the two is exactly the opposite. That is, the working voltage Vdd is coupled to the input end X of the first transistor Q1 and the input end X of the second transistor Q2. The output end Y of the second transistor Q2 is coupled to the first end of one of the LED lights 20A-20C, and the second end of one of the LED lights 20A-20C is coupled to the ground end. The output end Y of the first transistor Q1 is coupled to the input end X of the path switch unit 1048, and the output end Y of the path switch unit 1048 is coupled to the control module 2. The first switch unit 1044, the first energy-storing unit 1046, and the energy-releasing switch Qr are correspondingly connected to the first transistor Q1, the second transistor Q2, and the path switch unit 1048. Specifically, when the LED lights 20A-20C are the three-primary-color LED lights, the working voltage Vdd of the blue LED light 20C is about 3-3.5 volts, and the working voltage Vdd of the red LED light 20A and that of the green LED light 20B are about 1.6-1.8 volts. Therefore, by using the coupling manner in FIG. 6C, the current adjustment circuits 104A″-104C″ may respectively use the working voltages Vdd with different voltage values. In other words, the current adjustment circuits 104A″-104B″ may use 1.8-volt working voltage Vdd, and the current adjustment circuit 104C″ may use 3-volt working voltage Vdd so that the current adjustment circuits 104A″-104C″ can save power consumption and increase circuit efficiency.

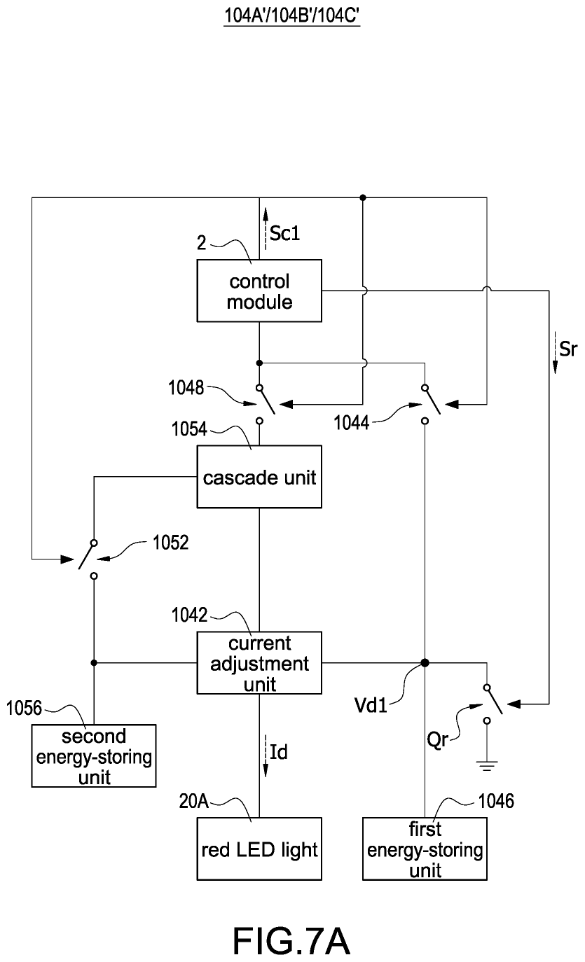

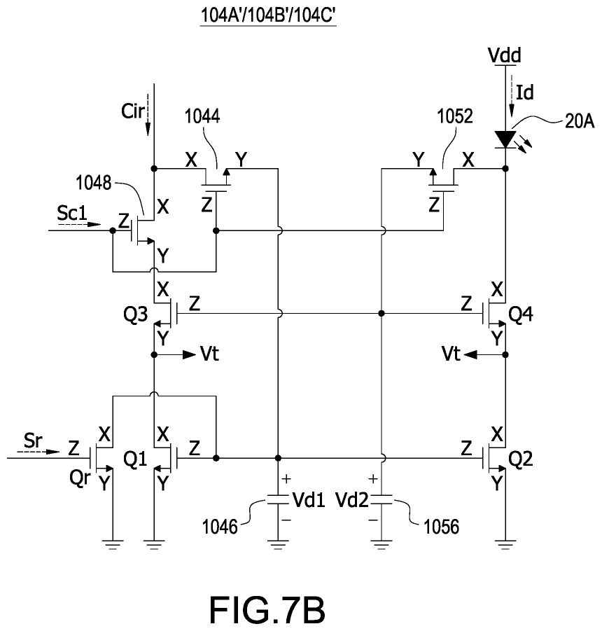

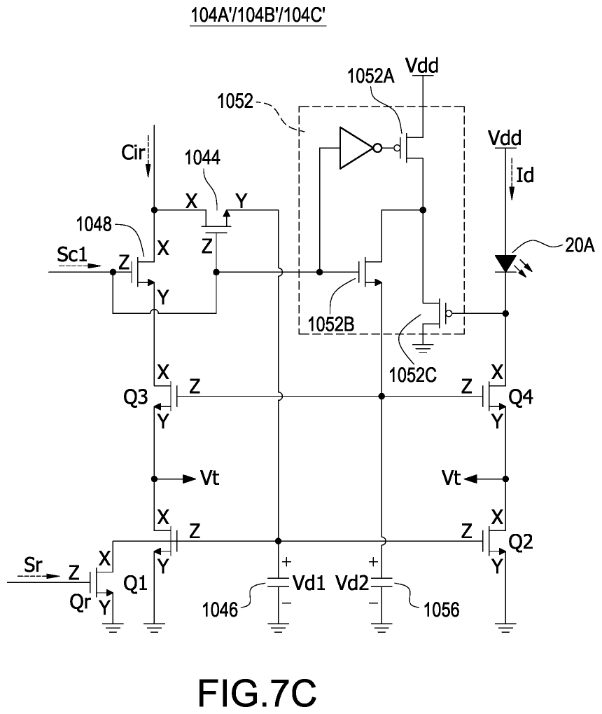

Please refer to FIG. 7A, which shows a block circuit diagram of a current storage module according to a second embodiment of the present disclosure, and also refer to FIG. 2 to FIG. 6C. The difference between the current adjustment circuit 104A′-104C′ in this embodiment and the current adjustment circuit 104A-104C shown in FIG. 6A is that each current adjustment circuit 104A′-104C′ further includes a second switch unit 1052, a cascade unit 1054, and a second energy-storing unit 1056. The second switch unit 1052 receives one (take a control signal Sc1 as an example) of multiples of four control signals Sc1-Sc4, and is coupled to the current adjustment unit 1042. The cascade unit 1054 is coupled to the second switch unit 1052 and the current adjustment unit 1042. The second energy-storing unit 1056 is coupled to the second switch unit 1052 and the cascade unit 1054, and the second energy-storing unit 1056 stores a second drive voltage Vd2 when the second switch unit 1052 is turned on.

When the control signal Sc1 is transited from a first level (for example, a lower signal level) to a second level (for example, a higher signal level), the second switch unit 1052 is turned on. The second energy-storing unit 1056 stores the second drive voltage Vd2 of driving the cascade unit 1054 by turning on the second switch unit 1052. The second drive voltage Vd2 can be acquired in the same manner as the first drive voltage Vd1. The cascade unit 1054 driven by the second drive voltage Vd2 controls an end voltage of the current adjustment unit 1042, and the end voltage fixes a ratio between one of the current commands Cir,Cig,Cib and the drive current Id. Specifically, since the ratio between one of the current commands Cir,Cig,Cib and the drive current Id will be affected by the end voltage of the current adjustment unit 1042, and the ratio adjustment will be inaccurate when the end voltage of the current adjustment unit 1042 is not accurately fixed, the brightness of one of the LED lights 20A-20C is affected and fails to produce the predetermined brightness. Therefore, the cascade unit 1054 is used to fix the end voltage Vt of the current adjustment unit 1042 to accurately control the brightness of one of the LED lights 20A-20C.

When the control signal Sc1 is transited from the second level (for example, a higher signal level) to the first level (for example, a lower signal level), the second switch unit 1052 is turned off. At this condition, the second energy-storing unit 1056 fails to acquire energy through the second switch unit 1052 so that the second energy-storing unit 1056 provides the remaining second drive voltage Vd2 to drive the cascade unit 1054. When the second switch unit 1052 is turned off, the stored (remaining) second drive voltage Vd2 can still drive the cascade unit 1054 so that the cascade unit 1054 still operates. Although the second switch unit 1052 is turned off, the cascade unit 1054 still controls the end voltage of the current adjustment unit 1042. The operation of the second switch unit 1052 when it is turned off is similar to that of the first switch unit 1044, and the detail description is omitted here for conciseness. In addition, the circuit components and operation manners not mentioned in this embodiment are the same as those in FIG. 6A, and the detail description is omitted here for conciseness.

Please refer to FIG. 7B, which shows a block circuit diagram of the current storage module according to a detailed of the second embodiment of the present disclosure, and also refer to FIG. 2 to FIG. 7A. The difference between the current adjustment circuit 104A′-104C′ (only one current adjustment circuit 104A-104C is exemplified for demonstration) in this embodiment and the current adjustment circuit 104A-104C shown in FIG. 6B is that the cascade unit 1054 includes a third transistor Q3 and a fourth transistor Q4. Both the third transistor Q3 and the fourth transistor Q4 has an input end X, an output end Y, and a control end Z. An input end X of the third transistor Q3 is coupled to the output end Y of the path switch unit 1048, an output end Y of the third transistor Q3 is coupled to the input end X of the first transistor Q1, and a control end Z of the third transistor Q3 is coupled to an output end Y of the second switch unit 1052 and a first end of the second energy-storing unit 1056. An input end X of the fourth transistor Q4 is coupled to the first end of one of the LED lights 20A-20C and an input end X of the second switch unit 1052, and the second end of one of the LED lights 20A-20C is coupled to the working voltage Vdd. An output end Y of the fourth transistor Q4 is coupled to the input end X of the second transistor Q2, and a control end Z of the fourth transistor Q4 is coupled to the control end Z of the third transistor Q3.

When the control signal Sc1 is transited from the first level (for example, a lower signal level) to the second level (for example, a higher signal level), the second switch unit 1052 is turned on. The working voltage Vdd (a positive-polarity voltage of the LED light 20A) charges the second energy-storing unit 1056 through the second switch unit 1052 so that the second energy-storing unit 1056 stores the second drive voltage Vd2. When the voltage value of the second drive voltage Vd2 rises enough to turn on the third transistor Q3 and the fourth transistor Q4, the second drive voltage Vd2 turns on the first transistor Q3 and the fourth transistor Q4 to drive the cascade unit 1054. At this condition, when the third transistor Q3 is turned on, an end voltage Vt is generated between the input end X of the first transistor Q1 and the ground end; when the fourth transistor Q4 is turned on, a node voltage between the input end X of the second transistor Q2 and the ground end is adjusted to be equal to the end voltage Vt. Since the end voltage Vt at the input end X of the first transistor Q1 is equal to the end voltage Vt at the input end X of the second transistor Q2, the current value of the drive current Id by mirroring is equal to the current value of one of the current commands Cir,Cig,Cib. Specifically, when a current difference (current error) between the current value of one of the current commands Cir,Cig,Cib and the current value of the drive current Id is generated, the brightness of one of the LED lights 20A-20C will not meet the brightness required by the control module 2. Therefore, a cascaded current-mirror circuit composed of the current adjustment unit 1042 and the cascade unit 1054 is provided to make the current difference (current error) be zero so that the brightness of one of the LED lights 20A-20C meets the brightness required by the control module 2.

In one embodiment, the circuit structure of the current adjustment circuit 104A′-104C′ is not limited to be implemented in FIG. 7B. Please refer to FIG. 7C, which shows a block circuit diagram of the current storage module according to a detailed of the third embodiment of the present disclosure, and also refer to FIG. 2 to FIG. 7B. FIG. 7C shows another structure of the cascaded current-mirror circuit. The second switch unit 1052 is composed of three series-connected cascaded switch components 1052A-1052C to make the current difference (current error) be smaller so as to accurately control the brightness of one of the LED lights 20A-20C to meet the brightness required by the control module 2. The circuit components and operation manners not mentioned in this embodiment are the same as those in FIG. 6B, and the detail description is omitted here for conciseness.

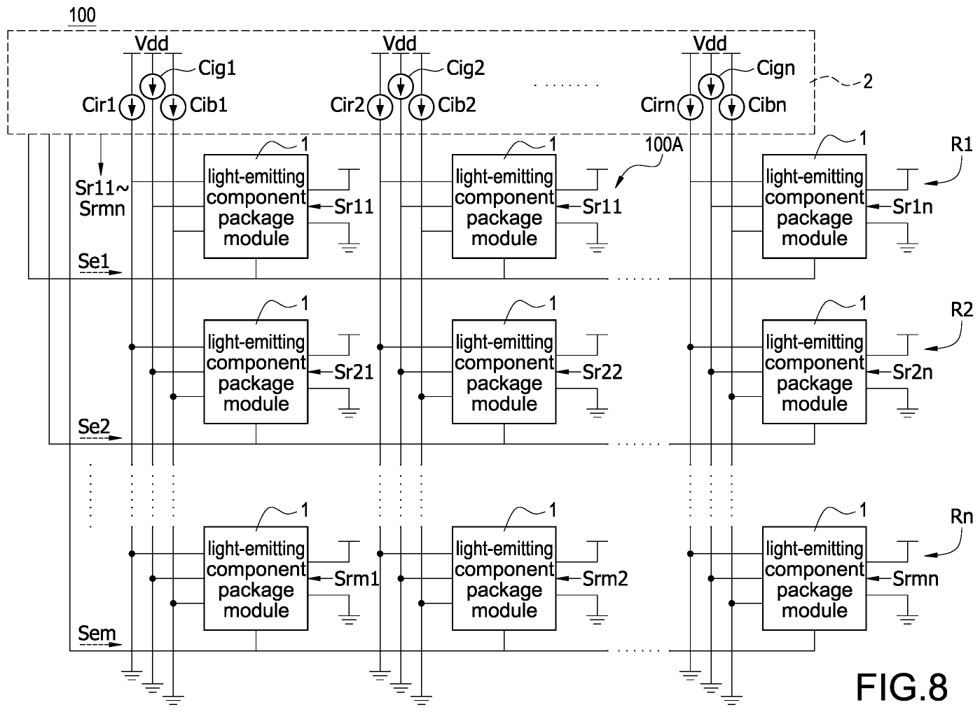

Please refer to FIG. 8, which shows a block diagram of a display composed of light-emitting component package modules according to the present disclosure, and also refer to FIG. 2 to FIG. 7C. The panel 100A of the display 100 includes a light-emitting matrix composed of multiple rows (R1-Rn) of or multiple columns of light-emitting component package modules 1 (multiple rows of light-emitting component package modules 1 are exemplified for demonstration). The control module 2 provides a plurality of enabled signals Se1-Sem to sequentially drive the light-emitting component package modules 1 with multiple rows R1-Rn, and provides a plurality of energy-releasing signals Srl1-Srmn to correspondingly release energy of the current adjustment circuits 104A-104C of each light-emitting component package module 1. Specifically, the control module 2 provides a plurality of enabled signals Se1-Sem by a frequency-sweeping loop of a frequency-sweeping manner to sequentially drive the light-emitting component package modules 1 with multiple rows R1-Rn. Since the light-emitting component package module 1 may be driven by a writing manner, the first enabled signal Se1 drives the current adjustment units 1042 of the first-row (R1) light-emitting component package modules 1. After the first energy-storing unit 1046 completely stores energy, the first enabled signal Se1 is disabled and then to provide the second enabled signal Se2 to drive the current adjustment units 1042 of the second-row (R2) light-emitting component package modules 1. When the first enabled signal Se1 is disabled, since the first-row (R1) light-emitting component package modules 1 still have the first drive voltage Vd1 capable of driving the current adjustment unit 1042, the first-row (R1) light-emitting component package modules 1 can still adjust the brightness of the LED light assemblies 20-1 to 20-4 according to one of the current commands Cir1-Cirn,Cig1-Cign,Cib1-Cibn. That is, an un-driven time period of turning off the first enabled signal Se1 is defined as that an elapsed time of one of plurality of rows R1-Rn (or one of the plurality of columns) be driven twice in the frequency-sweeping loop. For example, the first row R1 is driven for the first time at time t1 and the first row R1 is driven for the second time at time t2, and the un-driven time period is the time difference between the time t2 and the time t1. During the un-driven time period, the first-row (R1) light-emitting component package modules 1 can still adjust the brightness of the LED light assemblies 20-1 to 20-4 according to the corresponding current command Cir1-Cirn,Cig1-Cign,Cib1-Cibn.

Finally, the energy-releasing signals Srl1-Srmn can correspondingly release energy of the current adjustment circuits 104A-104C of light-emitting component package modules 1 with multiple rows R1-Rn to correspondingly clear (reset) the current commands Cir1-Cirn,Cig1-Cign,Cib1-Cibn stored in the current adjustment circuits 104A-104C of the light-emitting component package modules 1. Since each light-emitting component package module 1 includes multiples of two current storage units 104-1 to 104-4 (it is assumed that the number is four), and each current storage unit 104-1 to 104-4 includes three current adjustment circuits 104A-104C, the control module 2 or each current storage unit 104-1 to 104-4 has its own logic circuit (not shown) to generate three different energy-releasing signals Srl1-Srmn to correspondingly clear (reset) the current adjustment circuit 104A, the current adjustment circuit 104B, or the current adjustment circuit 104C. Take the energy-releasing signal Srl1 as an example, the energy-releasing signal Srl1 has three signals for clearing (resetting) the current command Cir1, the current command Cig1, or the current command Cib1 of the current adjustment circuit 104A, the current adjustment circuit 104B, or the current adjustment circuit 104C. Alternatively, after the energy-releasing signal Srl1 is provided to the first light-emitting component package module 1, additional logic circuit of the current storage unit 104-1 to 104-4 generates three different signals according to the energy-releasing signal Srl1 to clear (reset) the current commands Cir1-Cib1 of the current adjustment circuits 104A-104C.

In one embodiment, although the current value of the drive current Id is preferably equal to the current value of one of the current commands Cir,Cig,Cib, it is not limited under special considerations. For example, the current value needs to be scaled to be more suitable for controlling and adjusting the brightness of one of the LED lights 20A-20C. In other words, there is a multiplying relationship between the current value of the drive current Id and the current value of one of the current commands Cir,Cig,Cib so that the drive current Id is suitable for controlling and adjusting the brightness of one of the LED lights 20A-20C.

In one embodiment, the frequency-sweeping mode of the control module 2 is not limited to sequentially provide the enabled signals Se1-Sem from top to bottom or from left to right for triggering. The triggering sequence can be at intervals. For example, but not limited to, the odd-row of light-emitting component package modules 1 may be sequentially triggered, and then the even-row of light-emitting component package modules 1 are be sequentially triggered. After the first enabled signal Se1 is disabled, the first drive voltages Vd1 of the first-row (R1) light-emitting component package modules 1 will be gradually consumed. When the first drive voltage Vd1 is consumed to fail to drive the current adjustment unit 1042, the current adjustment unit 1042 can no longer control the brightness of one of the LED lights 20A-20C. Therefore, in order to avoid the first drive voltage Vd1 of the first-row (R1) light-emitting component package modules 1 fails to drive the current adjustment unit 1042, the frequency of the first enabled signal Se1 needs to be limited by the rate of consumption of the first drive voltage Vd1. In particular, the rate of consumption of the first drive voltage Vd1 is determined based on the picture recognition by the human eye's. That is, before the first drive voltage Vd1 is consumed until the current adjustment unit 1042 cannot be driven, the first level of the first drive voltage Vd1 is preferably converted to the second level thereof so as to avoid the current adjustment unit 1042 from being unable to control one of the LED lights 20A-20C.

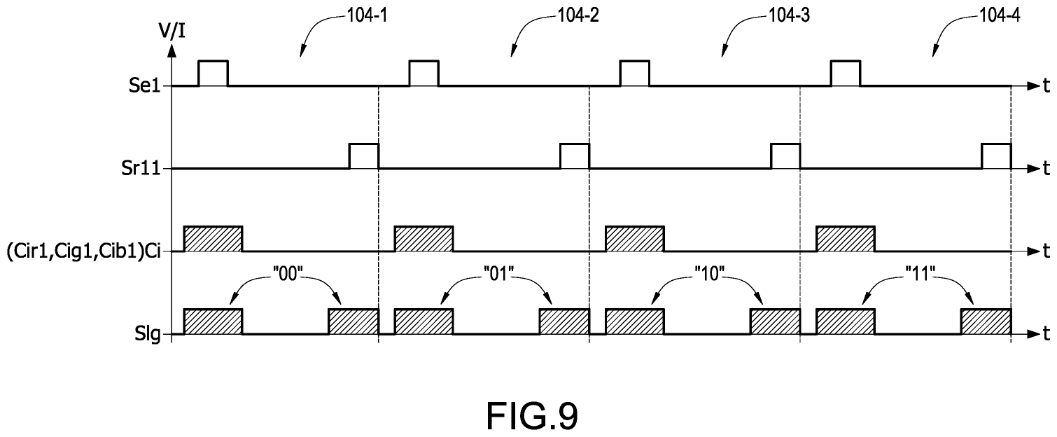

Please refer to FIG. 9, which shows a waveform diagram of controlling the light-emitting component package module according to the present disclosure, and also refer to FIG. 2 to FIG. 8. It is assumed that the light-emitting component package module 1 includes four current storage units 104-1 to 104-4, and the first enabled signal Se, the first current commands Cir1-Cib1, and the first energy-releasing signal Srl1 control the first light-emitting component package module 1. When the enabled signal Se1 is the first level (high level), the energy-releasing signal Srl1 is the second level (low level), and the logic signal assembly Slg provides the signal of logic “00”, the current storage unit 104-1 of the light-emitting component package module 1 writes the current commands Cir1-Cib1 to the current adjustment circuits 104A-104C. When the enabled signal Se1 is the second level (low level), the energy-releasing signal Srl1 is the first level (high level), and the logic signal assembly Slg provides the signal of logic “00”, the current storage unit 104-1 of the light-emitting component package module 1 clears (resets) the current commands Cir1-Cib1 to the current adjustment circuits 104A-104C. When the logic signal assembly Slg respectively provides the signal of logic “01710711”, the corresponding current storage units 104-2 to 104-4 respectively perform the operations of writing and clearing (resetting) according to the enabled signal Se1 and the energy-releasing signal Srl1. The remaining enabled signals Se2-Sem and the energy-releasing signals Srl2-Srmn control the remaining corresponding light-emitting component package modules 1 are similar to that of controlling the light-emitting component package module 1 by the enabled signal Se1 and the energy-releasing signal Srl1, and the detail description is omitted here for conciseness. In addition, the current values of the current commands Cir1-Cib1 written by each current storage unit 104-1 to 104-4 may be different, that is, the waveform amplitudes of the current commands Cir1-Cib1 may be different. In addition, the current values of the current commands Cir1,Cig1,Cib1 may be different, that is, the current values of the current commands Cir1,Cig1,Cib1 written by the current storage units 104-1 to 104-4. For the convenience of description, however, the current commands Cir1-Cib1 in this embodiment are represented by waveforms with the same amplitude.

The method manner of writing and clearing (resetting) of the present disclosure is provided to control multiple-row light-emitting component package modules 1 without using the conventional control manner of turning on the switches SW1-SWm. Therefore, when the control module 2 controls the multiple-row (R1-Rn) light-emitting component package modules 1, no dead time Td needs to be reserved between turned-off previous-row switches SW1-SWm and turned-on next-row switches SW1-SWm. It needs to write or clear (reset) the current commands Cir1-Cirn,Cig1-Cign,Cib1-Cibn during a short time interval when the enabled signals Se2-Sem and the energy-releasing signals Srl2-Srmn at the first level. Accordingly, the panel 100A of the display 100 can be controlled to display the desired screen, and the number of frames and image clarity can be significantly increased.

Although the present disclosure has been described with reference to the preferred embodiment thereof, it will be understood that the present disclosure is not limited to the details thereof. Various substitutions and modifications have been suggested in the foregoing description, and others will occur to those of ordinary skill in the art. Therefore, all such substitutions and modifications are intended to be embraced within the scope of the present disclosure as defined in the appended claims.

What is claimed is:

1. A light-emitting component package module for a display and a backlight, the light-emitting component package module driven by a control module, the light-emitting component package module comprising:
a drive module configured to receive a drive signal of the control module, the drive signal having an enabled signal and a current command assembly, and the drive module comprising:
a timing control unit configured to receive the enabled signal, and
a current storage module coupled to the timing control unit, and
an LED light module having multiples of two LED light assemblies, the multiples of two LED light assembly coupled to the drive module,
wherein the current storage module comprises multiples of two current storage units corresponding to the multiples of two LED light assemblies; each current storage unit receives the current command assembly; the timing control unit provides multiples of two control signals to correspondingly drive the multiples of two current storage units according to the enabled signal; the driven current storage units control the brightness of the corresponding LED light assemblies according to the current command assembly.

2. The light-emitting component package module as claimed in claim 1, wherein the multiples of two LED light assemblies are respectively arranged in equal number at both sides along an axis, and the drive module is coupled to the multiples of two LED light assemblies without blocking light source paths of the multiples of two LED light assemblies.

3. The light-emitting component package module as claimed in claim 2, wherein the multiple is a power of two; the multiples of two LED light assemblies are respectively arranged in equal number in a first quadrant, a second quadrant, a third quadrant, and a fourth quadrant of a coordinate; the drive module is arranged in an origin of the coordinate.

4. The light-emitting component package module as claimed in claim 1, wherein each LED light assembly comprises a red LED light, a green LED light, and a blue LED light, and the current command assembly comprises a red light current command, a green light current command, and a blue light current command; each current storage unit controls the brightness of the red LED light according to the red light current command, controls the brightness of the green LED light according to the green light current command, and controls the brightness of the blue LED light according to the blue light current command; or each LED light assembly comprises an LED light and the current command assembly comprises a current command, and each current storage unit controls the brightness of the LED light according to the current command.

5. The light-emitting component package module as claimed in claim 1, wherein each current storage unit comprises at least one current adjustment circuit, and each of the at least one current adjustment circuit comprises:
a path switch unit coupled to one of the current commands of the current command assembly, and configured to receive one of the multiples of two control signals,
a current adjustment unit coupled to the path switch unit and one of the LED lights of one of the LED light assemblies,
a first switch unit coupled to the current adjustment unit, and configured to receive one of the control signals of the multiples of two control signals, and
a first energy-storing unit coupled to the first switch unit and the current adjustment unit,
wherein when one of the control signals is transited from a first level to a second level, the current adjustment unit receives one of the current commands of the current command assembly by turning on the path switch unit, and the first energy-storing unit stores a first drive voltage of driving the current adjustment unit by turning on the first switch unit; the current adjustment unit driven by the first drive voltage generates a drive current according to one of the current commands to control the brightness of one of the LED lights.

6. The light-emitting component package module as claimed in claim 5, wherein when one of the control signals is transited from the second level to the first level, the path switch unit is turned off so that the current adjustment unit fails to receive one of the current commands, and the first switch unit is turned off so that the first energy-storing unit provides the remaining first drive voltage to drive the current adjustment unit; the current adjustment unit maintains the brightness of one of the LED lights according to the first drive voltage.

7. The light-emitting component package module as claimed in claim 5, wherein each of the at least one current adjustment circuit comprises:
an energy-releasing switch coupled to the first energy-storing unit, and configured to receive an energy-releasing signal,
wherein when the energy-releasing switch is turned on by the energy-releasing signal, the first drive voltage releases energy through the energy-releasing switch and fails to drive the current adjustment unit.

8. The light-emitting component package module as claimed in claim 5, wherein each of the at least one current adjustment circuit comprises:
a second switch unit coupled to the current adjustment unit, and configured to receive one of the control signals,
a cascade unit coupled to the second switch unit and the current adjustment unit, and
a second energy-storing unit coupled to the second switch unit and the cascade unit,
wherein when one of the control signals is transited from the first level to the second level, the second energy-storing unit stores a second drive voltage of driving the cascade unit by turning on the second switch unit; the cascade unit driven by the second drive voltage controls an end voltage of the current adjustment unit, and the end voltage fixes a ratio between one of the current commands and the drive current.

9. The light-emitting component package module as claimed in claim 8, wherein the current adjustment unit comprises:
a first transistor having an input end, an output end, and a control end; the input end coupled to the path switch unit, the output end coupled to a ground end, and the control end coupled to the first switch unit and the first energy-storing unit, and
a second transistor having an input end, an output end, and a control end; the input end coupled to one of the LED lights, the output end coupled to the ground end, and the control end coupled to the control end of the first transistor;
wherein when the first switch unit is turned on, one of the current commands charges the first energy-storing unit so that the first energy-storing unit stores the first drive voltage, and the first drive voltage turns on the first transistor and the second transistor; when the path switch unit is turned on, one of the current commands flows from the input end of the first transistor to the output end of the first transistor, and the drive current corresponding to one of the current commands is generated from the input end of the second transistor to the output end of the second transistor by mirroring; the drive current flows through one of the LED lights to control the brightness of one of the LED lights.

10. The light-emitting component package module as claimed in claim 9, wherein when the path switch unit and the switch unit are turned off, one of the current commands does not charge the energy-storing unit so that the energy-storing unit provides the remaining first drive voltage to turn on the second transistor to maintain the brightness of one of the LED lights.

11. The light-emitting component package module as claimed in claim 9, wherein the cascade unit comprises:
a third transistor having an input end, an output end, and a control end; the input end coupled to the path switch unit, the output end coupled to the input end of the first transistor, and the control end coupled to the second switch unit and the second energy-storing unit, and
a fourth transistor having an input end, an output end, and a control end; the input end coupled to one of the LED lights, the output end coupled to the input end of the second transistor, and the control end coupled to the output end of the second transistor,
wherein when the second switch unit is turned on, the second energy-storing unit is charged so that the second energy-storing unit stores the second drive voltage, and the second drive voltage turns on the third transistor and the fourth transistor; the third transistor is turned on so that the input end of the first transistor has the end voltage, and the fourth transistor is turned on so that a node voltage of the input end of the second transistor is adjusted to be equal to the end voltage and a current value of the drive current is equal to a current value of one of the current commands.

12. A display comprising:
a light-emitting matrix comprising a plurality of rows or a plurality of columns, each row or each column comprising a plurality of light-emitting component package modules claimed in claim 1, and
a control module coupled to the light-emitting matrix,
wherein the control module provides a plurality of enabled signals to sequentially drive the plurality of rows or the plurality of columns.

13. The display as claimed in claim 12, wherein the control module provides a plurality of enabled signals in a frequency-sweeping loop to sequentially drive the plurality of rows or the plurality of columns.

14. The display as claimed in claim 13, wherein an un-driven time period is defined as that an elapsed time of one of plurality of rows or one of the plurality of columns be driven twice in the frequency-sweeping loop; during the un-driven time period, the light-emitting component package modules of one of the rows or of one of the columns adjust the brightness of the LED light assemblies according to the corresponding current command assembly.
